(19) United States
(12) Patent Application Publication
(10) Pub. No.: US 2013/0277788 A1
(43) Pub. Date: Oct. 24, 2013

(54) IMAGING UNIT AND IMAGING DEVICE

(71) Applicant: SONY CORPORATION, Tokyo (JP)

(72) Inventor: Yasuhide Nihei, Kanagawa (JP)

(73) Assignee: Sony Corporation, Tokyo (JP)

(21) Appl. No.: 13/788,478

(22) Filed: Mar. 7, 2013

(30) Foreign Application Priority Data
Apr. 24, 2012 (JP) 2012-099121

(51) Int. Cl. H01L 27/146

(52) U.S. Cl. CPC H01L 27/14618
USPC 257/434

(57) ABSTRACT

There is provided an imaging unit including a light-transmissive member through which photographing light brought in via an optical system is transmitted, an image sensor that is disposed facing the light-transmissive member and on which photographing light that has been transmitted through the light-transmissive member is incident so as to convert the incident photographing light into electrical signals, and a holding member that has a disposition hole and holds the light-transmissive member. The light-transmissive member has an outer circumferential face to which an adhesive is applied so as to be attached to and held by the holding member in a state of being disposed in the disposition hole, and the adhesive has light absorptivity and a refractive index that is substantially identical to a refractive index of the light-transmissive member.

### BACKGROUND

The present disclosure relates to the technical field of an imaging unit and an imaging device. Particularly, the present disclosure relates to the technical field of preventing incidence of unnecessary light on an image sensor by bonding a light-transmissive member that is disposed facing the image sensor to a holding member using an adhesive having light absorptivity and the same refractive index as the light-transmissive member.

In various imaging devices such as a video camera, a still camera, and the like, an optical system having lenses, a shutter, a diaphragm, and the like therein and an imaging unit having an image sensor on which photographing light brought in via the optical system is incident are disposed.

As the image sensor, for example, a CCD (Charge Coupled Device), a CMOS (Complementary Metal Oxide Semiconductor), or the like is used, and such an image sensor generates images by converting photographing light into electrical signals.

In the imaging unit, a light-transmissive member that is disposed facing the image sensor is provided in addition to the image sensor, and photographing light is transmitted through the light-transmissive member and then is incident on the image sensor. The light-transmissive member is held by a holding member such as a light shielding member, a circuit board, or the like, and held by way of, for example, bonding to the holding member, or the like while being disposed in a disposition hole formed in the holding member.

For such an imaging device as described above, it is necessary to attain the enhancement of image quality by suppressing incidence of unnecessary light that may become stray light out of light brought inside the device during photographing on the image sensor. Particularly, as miniaturization of imaging devices has developed in recent years, the distance between an image sensor and a light-transmissive member has become short, and light that is reflected on an inner circumferential face of the light-transmissive member formed by a disposition hold is easily incident on the image sensor as stray light, and therefore, it is important to reduce the incidence of unnecessary light reflected on the inner circumferential face on the image sensor.

Thus, there is an imaging device in the related art in which incidence of unnecessary light on an image sensor is suppressed by forming an inner circumferential face of a light-transmissive member to be an inclined face so as to cause light to be reflected on the inclined face toward an object side (for example, refer to Japanese Unexamined Patent Application Publication No. 2008-17505).

In addition, there is another imaging device in the related art in which incidence of unnecessary light on an image sensor is suppressed by applying an opaque resin onto an inner circumferential face formed on a holding member (circuit board) so as to cause light to be incident on the inner side of the opaque resin (for example, refer to Japanese Unexamined Patent Application Publication No. 2003-101002).

Furthermore, there is still another imaging device in the related art in which incidence of unnecessary light on an image sensor is suppressed by coating an antireflective film over an inner circumferential face formed on a holding member (circuit board) so as to prevent the reflection of light with the antireflective film (for example, refer to Japanese Unexamined Patent Application Publication No. 2001-111873).

### SUMMARY

However, in the imaging device disclosed in Japanese Unexamined Patent Application Publication No. 2008-17505, light is set to be reflected on the inclined face toward the object side, but there is a possibility of light that has been reflected on the inclined face being reflected again on another part of the imaging unit, and thereby being incident on theimage sensor, which results in a difficulty in sufficiently suppressing the incidence of unnecessary light on the image sensor.

In addition, in the imaging device disclosed in Japanese Unexamined Patent Application Publication No. 2003-101002, light is set to be incident on the inner side of the opaque resin applied onto the inner circumferential face formed on the holding member, but light is reflected on the surface of the opaque resin causing the incidence of unnecessary light on the image sensor, which also results in a difficulty in sufficiently suppressing the incidence of unnecessary light on the image sensor.

Furthermore, in the imaging device disclosed in Japanese Unexamined Patent Application Publication No. 2001-111873, reflection of light is set to be prevented by the antireflective film coated over the inner circumferential face formed on the holding member, but coating the antireflective film over the inner circumferential face having a small surface area is difficult, and accordingly, a satisfactory coating state of the antireflective film may not be secured, and thus, there is concern that it is hard to sufficiently suppress the incidence of unnecessary light on the image sensor.

It is desirable to provide an imaging unit and an imaging device according to the present disclosure which resolve the above-described circumstances and prevent the incidence of unnecessary light on an image sensor.

According to an embodiment of the present disclosure, there is provided an imaging unit including a light-transmissive member through which photographing light brought in via an optical system is transmitted, an image sensor that is disposed facing the light-transmissive member and on which photographing light that has been transmitted through the light-transmissive member is incident so as to convert the incident photographing light into electrical signals, and a holding member that has a disposition hole and holds the light-transmissive member. The light-transmissive member has an outer circumferential face to which an adhesive is applied so as to be attached to and held by the holding member in a state of being disposed in the disposition hole. The adhesive has light absorptivity and a refractive index that is substantially identical to a refractive index of the light-transmissive member.

Thus, in the imaging unit, light approaching an outer circumferential face of the light-transmissive member is transmitted through the outer circumferential face, incident on the adhesive, and then absorbed by the adhesive.

Further, it is desirable that the imaging unit further includes a light shielding member serving as the holding member. The image sensor may be mounted on a circuit board, and the holding member may be installed on the circuit board and there is a disposition space in which the image sensor is disposed.

The light shielding member is provided as a holding member, the image sensor is mounted on the circuit board, and the holding member is installed in the circuit board so that the disposition space in which the image sensor is disposed is formed, and thereby the image sensor is shielded from outside.

Further, it is desirable that the imaging unit further includes a circuit board serving as the holding member. The image sensor may be bonded to the holding member by a conductive agent.

The circuit board is provided as a holding member, and the image sensor is bonded to the holding member by the conductive agent, and thereby the image sensor is disposed close to the holding member.

Further, it is desirable that a difference between refractive indexes of the light-transmissive member and the adhesive may be set to be 0.3 or lower.

By setting the difference between the refractive indexes of the light-transmissive member and the adhesive to be 0.3 or lower, the reflection of stray light from the light-transmissive member to the adhesive on a surface of the adhesive is prevented.

Further, it is desirable that a difference between refractive indexes of the light-transmissive member and the adhesive may be set to be 0.2 or lower.

By setting the difference between the refractive indexes of the light-transmissive member and the adhesive to be 0.2 or lower, the reflection of stray light from the light-transmissive member to the adhesive on a surface of the adhesive is further prevented.

Further, it is desirable that an outer circumference of at least one of an incidence face and an emission face of the photographing light of the light-transmissive member coincides with an inner circumference of at least one of a face of the adhesive closest to an object side and a face of the adhesive closest to an image side.

By causing at least one outer circumference of the incidence face and the emission face of the photographing light of the light-transmissive member to coincide with at least one inner circumference of the face of the adhesive closest to the object side and the face thereof closest to the image side, the attachment area of the adhesive to the outer circumferential face of the light-transmissive member is large.

Further, it is desirable that the outer circumferences of the incidence face and the emission face of the light-transmissive member coincide with the inner circumferences of the face of the adhesive closest to the object side and the face of the adhesive closest to the image side, respectively.

By causing the outer circumferences of the incidence face and the emission face of the light-transmissive member to coincide with the inner circumferences of the face of the adhesive closest to the object side and the face thereof closest to the image side, respectively, the adhesive is attached to the entire outer circumferential faces of the light-transmissive member.

Further, it is desirable that the adhesive is applied to an outer circumferential part of at least one of an incidence face and an emission face of the photographing light of the light-transmissive member.

By applying the adhesive to at least one outer circumferential part of the incidence face and the emission face of the photographing light of the light-transmissive member, the attachment area of the adhesive to the outer circumferential face of the light-transmissive member is large even when the adhesive position of the adhesive to the light-transmissive member is deviated.

Further, it is desirable that the adhesive is applied to each of the outer circumferential parts of the incidence face and the emission face of the light-transmissive member.

By applying the adhesive to each of the outer circumferential parts of the incidence face and the emission face of the light-transmissive member, the adhesive is attached to the entire outer circumferential face of the light-transmissive member even when the adhesive position of the adhesive to the light-transmissive member is deviated.

Further, it is desirable that at least one of an opening end of the disposition hole on an object side and an opening end of the disposition hole end on an image side in the holding member coincides with an outer circumference of at least one of a face of the adhesive closest to an object side and a face of the adhesive closest to an image side.

By causing at least one of the opening end of the disposition hole on the object side and the opening end thereof on the image side in the holding member to coincide with at least one outer circumference of the face of the adhesive closest to the object side and the face thereof closest to the image side, the attachment area of the adhesive to the inner circumferential face of the holding member is large

Further, it is desirable that the opening end on the object side and the opening end on the image side in the holding member coincide with the outer circumferences of the face of the adhesive closest to the object side and the face of the adhesive closest to the image side, respectively.

By causing the opening end on the object side and the opening end on the image side in the holding member to respectively coincide with the outer circumferences of the face of the adhesive closest to the object side and the face thereof closest to the image side, the adhesive is attached to the entire inner circumferential face of the holding member.

Further, it is desirable that the adhesive is applied to at least one of an inner circumferential part of a face of the holding member closest to an object side and an inner circumferential part of a face of the holding member closest to an image side.

By applying the adhesive to at least one of the inner circumferential part of the face of the holding member closest to the object side and the inner circumferential part of the face thereof closest to the image side, the attachment area of the adhesive to the inner circumferential face of the holding member is large even when the adhesive position of the adhesive to the holding member is deviated.

Further, it is desirable that the adhesive is applied to the inner circumferential part of the face of the holding member closest to the object side and the inner circumferential part of the face of the holding member closest to the image side.

By applying the adhesive to the inner circumferential part of the face of the holding member closest to the object side and the inner circumferential part of the face thereof closest to the image side, the adhesive is attached to the entire inner circumferential face of the light-transmissive member even when the adhesive position of the adhesive to the light-transmissive member is deviated.

Further, it is desirable that the adhesive is formed of a black material or a material in which a black mixture is mixed.

By forming the adhesive of a black material or a material in which a black mixture is mixed, light incident on the adhesive is absorbed by the black material or the black mixture.

According to an embodiment of the present disclosure, there is provided an imaging device including an optical system, and an imaging unit that is disposed on the image side of the optical system. The imaging unit may include a light-transmissive member through which photographing light brought in via the optical system is transmitted, an image sensor that is disposed facing the light-transmissive member and on which photographing light that has been transmitted through the light-transmissive member is incident so as to convert the incident photographing light into electrical signals, and a holding member that has a disposition hole and holds the light-transmissive member. The light-transmissive member has an outer circumferential face to which an adhesive is applied so as to be attached to and held by the holding member in a state of being disposed in the disposition hole. The adhesive has light absorptivity and a refractive index that is substantially identical to a refractive index of the light-transmissive member.

Thus, in the imaging device, light approaching the outer circumferential face of the light-transmissive member is transmitted through the outer circumferential face, incident on the adhesive, and absorbed by the adhesive.

The imaging unit according to an embodiment of the present disclosure includes a light-transmissive member through which photographing light brought in via an optical system is transmitted, an image sensor that is disposed facing the light-transmissive member and on which photographing light that has been transmitted through the light-transmissive member is incident so as to convert the incident photographing light into electrical signals, and a holding member that has a disposition hole so as to hold the light-transmissive member, the light-transmissive member has an outer circumferential face to which an adhesive is applied so as to be attached to and held by the holding member while being disposed in the disposition hole, and the adhesive has light absorptivity and the same refractive index as the light-transmissive member.

Thus, since stray light approaching the outer circumferential face of the light-transmissive member is transmitted through the outer circumferential face, incident on the adhesive, and absorbed by the adhesive, the incidence of unnecessary light on the image sensor can be prevented.

According to an embodiment of the present disclosure, a light shielding member is provided as the holding member, the image sensor is mounted on a circuit board, and the holding member is installed on the circuit board so that a disposition space in which the image sensor is disposed is formed.

Thus, the image sensor is protected, adhesion of dust to the image sensor is prevented, and further the incidence of unnecessary light on the image sensor can be prevented.

According to the embodiment of the present disclosure, a circuit board is provided as the holding member, and the image sensor is bonded to the holding member by a conductive agent.

Thus, thinness of the imaging unit is attained, and the incidence of unnecessary light on the image sensor can be prevented.

According to the embodiment of the present disclosure, the difference between refractive indexes of the light-transmissive member and the adhesive is set to be 0.3 or lower.

Thus, the reflection of stray light from the light-transmissive member to the adhesive on the surface of the adhesive is suppressed, and stray light approaching the image sensor can be reduced.

According to the embodiment of the present disclosure, the difference between refractive indexes of the light-transmissive member and the adhesive is set to be 0.2 or lower.

Thus, the reflection of stray light from the light-transmissive member to the adhesive on the surface of the adhesive is further suppressed, and stray light approaching the image sensor can be further reduced.

According to the embodiment of the present disclosure, at least one outer circumference of the incidence face and the emission face of the photographing light of the light-transmissive member coincides with at least one inner circumference of the face of the adhesive closest to the object side and the face thereof closest to the image side.

Thus, since the attachment area of the adhesive to the outer circumferential face of the light-transmissive member is large, stray light approaching the image sensor can be reduced.

According to the embodiment of the present disclosure, the outer circumferences of the incidence face and the emission face of the light-transmissive member coincide with the inner circumferences of the face of the adhesive closest to the object side and the face thereof closest to the image side, respectively.

Thus, since the adhesive is attached to the entire outer circumferential face of the light-transmissive member, stray light approaching the image sensor can be further reduced.

According to the embodiment of the present disclosure, the adhesive is applied to at least one outer circumferential part of the incidence face and the emission face of the photographing light of the light-transmissive member.

Thus, since the attachment area of the adhesive to the outer circumferential face of the light-transmissive member is large even when the adhesion position of the adhesive to the light-transmissive member is deviated, stray light approaching the image sensor can be further reduced.

According to the embodiment of the present disclosure, the adhesive is applied to each of the outer circumferential parts of the incidence face and the emission face of the light-transmissive member.

Thus, since the adhesive is attached to the entire outer circumferential face of the light-transmissive member even when the adhesion position of the adhesive to the light-transmissive member is deviated, stray light approaching the image sensor can be further reliably reduced.

According to the embodiment of the present disclosure, at least one of the opening end of the disposition hole on the object side and the opening end thereof on the image side in the holding member coincides with at least one outer circumference of the face of the adhesive closest to the object side and the face thereof closest to the image side.

Thus, since the attachment area of the adhesive to the inner circumferential face of the holding member is large, stray light approaching the image sensor can be reduced.

According to the embodiment of the present disclosure, the opening end on the object side and the opening end on the image side in the holding member respectively coincide with the outer circumferences of the face of the adhesive closest to the object side and the face thereof closest to the image side.

Thus, since the adhesive is attached to the entire inner circumferential face of the holding member, stray light approaching the image sensor can be further reduced.

According to the embodiment of the present disclosure, the adhesive is applied to at least one of the inner circumferential part of the face of the holding member closest to the object side and the inner circumferential part of the face thereof closest to the image side.

Thus, since the attachment area of the adhesive to the inner circumferential face of the holding member is large even when the adhesion position of the adhesive to the holding member is deviated, stray light approaching the image sensor can be even further reduced.

According to the embodiment of the present disclosure, the adhesive is applied to the inner circumferential part of the face of the holding member closest to the object side and the inner circumferential part of the face thereof closest to the image side.

Thus, since the adhesive is attached to the entire inner circumferential face of the holding member even when the adhesion position of the adhesive to the holding member is deviated, stray light approaching the image sensor can be further reliably reduced.

According to the embodiment of the present disclosure, the adhesive is formed of a black material or a material in which a black mixture is mixed.

Thus, satisfactory light absorptivity of the adhesive can be secured.

The imaging device according to another embodiment of the present disclosure includes an optical system, and an imaging unit that is disposed on the image side of the optical system, the imaging unit includes a light-transmissive member through which photographing light brought in via the optical system is transmitted, an image sensor that is disposed facing the light-transmissive member and on which photographing light that has been transmitted through the light-transmissive member is incident so as to convert the incident photographing light into electrical signals, and a holding member that has a disposition hole and holds the light-transmissive member, the light-transmissive member has an outer circumferential face to which an adhesive is applied so as to be attached to and held by the holding member while being disposed in the disposition hole, and the adhesive has light absorptivity and the same refractive index as the light-transmissive member.

Thus, since stray light approaching the outer circumferential face of the light-transmissive member is transmitted through the outer circumferential face, is incident on the adhesive, and absorbed by the adhesive, the incidence of unnecessary light on the image sensor can be prevented.

### BRIEF DESCRIPTION OF THE DRAWINGS

FIG. 1 shows, along with FIGS. 2 to 10, a best mode according to an embodiment of the present disclosure, and is a schematic perspective diagram of an imaging device;

FIG. 2 is a schematic enlarged cross-sectional diagram of a lens unit and an imaging unit;

FIG. 3 is a conceptual diagram showing an incidence state of stray light on the imaging unit;

FIG. 4 shows, along with FIGS. 5 to 7, an application state of an adhesive in the imaging unit, and is an enlarged cross-sectional diagram showing an example in which an outer circumference of a light-transmissive member coincides with an inner circumference of the adhesive and an opening end of a holding member coincides with an outer circumference of the adhesive;

FIG. 5 is an enlarged cross-sectional diagram showing an example in which the adhesive is applied to an outer circumferential part of the light-transmissive member;

FIG. 6 is an enlarged cross-sectional diagram showing an example in which the adhesive is applied to an inner circumferential part of the holding member;

FIG. 7 is an enlarged cross-sectional diagram showing an example in which the adhesive is applied to the outer circumferential part of the light-transmissive member and the inner circumferential part of the holding member;

FIG. 8 is a schematic cross-sectional diagram of an imaging unit according to a second embodiment of the present disclosure;

FIG. 9 is a schematic enlarged cross-sectional diagram showing an example in which a filter film is formed on the surface of the light-transmissive member; and

FIG. 10 is a block diagram of the imaging device.

### DETAILED DESCRIPTION OF THE EMBODIMENT(S)

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

The preferred embodiments to be shown below are implemented by applying an imaging device according to the present disclosure to a mobile telephone having a camera, and an imaging unit according to the present disclosure to an imaging unit provided in the mobile telephone.

Note that the application scope of the present disclosure is not limited to such a mobile telephone having a camera and an imaging unit provided in the mobile telephone having a camera, and the technology can be widely applied to various kinds of imaging devices, for example, a still camera, a video camera, and one incorporated into other devices, and various kinds of imaging units provided in such imaging devices.

In the description below, it is assumed that the front, rear, upper, lower, right, and left directions are based on the direction in which a photographer views during imaging of a camera provided in a mobile telephone. Thus, the object side is the front side and the photographer side (image side) is the rear side.

Note that the front, rear, upper, lower, right, and left directions to be shown below are set for the sake of convenience in description, and directions are not limited to the directions in the implementation according to an embodiment of the present disclosure.

### [Outlined Configuration of Imaging Device]

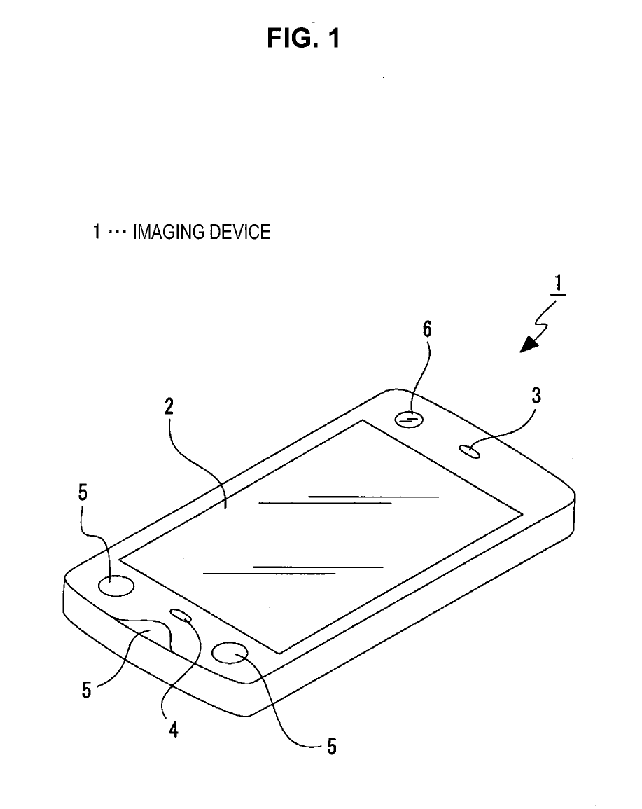

An imaging device (mobile telephone) 1 is provided with, for example, a display panel 2, a speaker 3, a microphone 4, and operation keys 5, 5, . . . on a face on one side thereof (refer to FIG. 1).

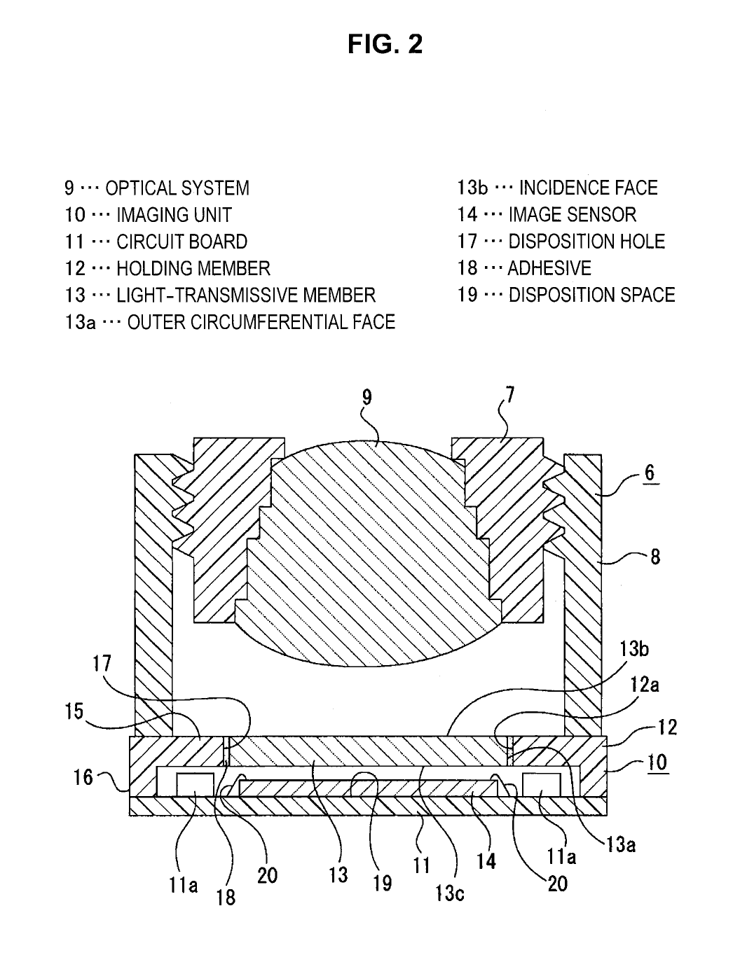

A lens unit 6 having a holder 7 and an optical system 9 such as lenses, a lens group, a shutter, and a diaphragm held by the holder 7 is incorporated in the imaging device 1 (refer to FIG. 2).

The holder 7 is supported by a drive ring 8 so as to be movable in the front-rear direction (optical axis direction). Note that FIG. 2 conceptually shows the holder 7, the optical system 9, and the drive ring 8, and each lens and lens group of the optical system 9 may be held by a separate holder so as to be separately movable in the front-rear direction, or may be fixed.

### [Configuration of Imaging Unit According to First Embodiment]

Hereinafter, an imaging unit 10 according to a first embodiment will be described (refer to FIG. 2).

The imaging unit 10 is disposed in the rear side of the lens unit 6, that is, on the image side. The imaging unit 10 has a circuit board 11, a holding member 12, a light-transmissive member 13, and an image sensor 14.

A circuit pattern that is not shown in the drawing is formed on the front face of the circuit board 11, and a plurality of electric components 11a, 11a, . . . are mounted on the circuit pattern.

The holding member 12 is a light shielding member that shields light and has a disposition part 15 facing in the front-rear direction and an attached part 16 protruding from an outer circumferential part of the disposition part 15 toward the rear side, and the rear face of the attached part 16 is attached to the outer circumferential part of the circuit board 11. A rectangular disposition hole 17 that passes through the disposition part 15 to the front and rear sides is formed in the disposition part 15. An inner circumferential face 12a that extends in the disposition hole 17 in the circumferential direction is formed in the holding member 12.

The light-transmissive member 13 is formed to have a rectangular plate shape using, for example, parallel plate glass, a resin film, or the like, and a refractive index thereof is about 1.3 to 1.7, for example, set to be 1.51 to 1.52. The light-transmissive member 13 has an outer circumferential face 13a, an incidence face 13b that serves as a front face, and an emission face 13c that serves as a rear face. Using an adhesive 18, the light-transmissive member 13 adheres to and is held by the holding member while being inserted into the disposition hole 17. Thus, the adhesive 18 is applied to the outer circumferential face 13a of the light-transmissive member 13 and the inner circumferential face 12a of the holding member 12.

The adhesive 18 is formed of a material having light absorptivity and the same refractive index as the light-transmissive member 13, for example, an epoxy-based adhesive or an acrylic-based adhesive. The refractive index of the adhesive 18 is the same as that of the light-transmissive member 13, and set to be, for example, 1.51 to 1.52. Note that the difference between the refractive indexes of the light-transmissive member 13 and the adhesive 18 is desirably 0.3 or lower, and more desirably 0.2 or lower.

The adhesive 18 is formed of a black material or a material in which a black mixture is mixed, and desirably has high light absorptivity. As the black material or mixture, for example, carbon is used.

As described above, by attaching the holding member 12 to the circuit board 11 and holding the light-transmissive member 13 using the holding member 12, a disposition space surrounded by the circuit board 11, the holding member 12, and the light-transmissive member 13 is formed.

The image sensor 14 is mounted on the front face of the circuit board 11 so as to be disposed facing the light-transmissive member 13. The image sensor 14 is formed in a rectangular shape slightly smaller than that of the light-transmissive member 13, and connected to the circuit pattern formed on the front face of the circuit board 11 by, for example, wires 20, 20, . . . .

### [Incidence of Light]

During imaging in the imaging device 1 having the imaging unit 10, photographing light that is brought in via the optical system 9 is transmitted through the light-transmissive member 13 and then is incident on the image sensor 14, the incident photographing light is converted into electrical signals by the image sensor 14, and an image is thereby generated.

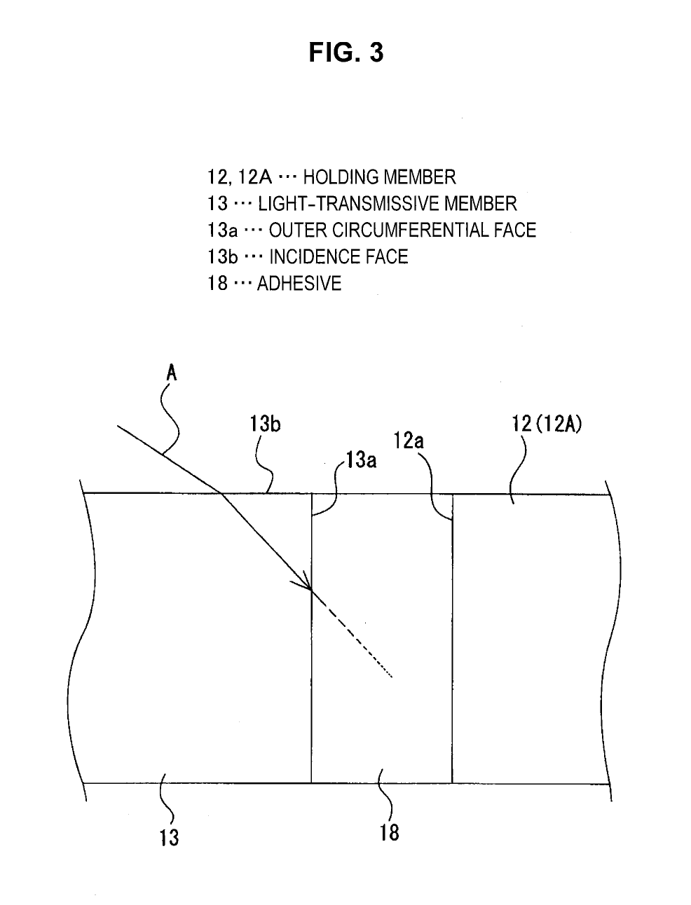

At this moment, part of light penetrating the lens unit 6 is incident from the incidence face 13b of the light-transmissive member 13 and then advances toward the outer circumferential face 13a as stray light (refer to the light A shown in FIG. 3). Since the refractive index of the adhesive 18 is set to be the same as that of the light-transmissive member 13, the stray light incident from the incidence face 13b is incident on the adhesive 18 from the outer circumferential face 13a without being reflected on the outer circumferential face 13a. The stray light incident on the adhesive 18 is absorbed by the adhesive 18 having light absorptivity, and stray light is not emitted from the adhesive 18 or emission from the adhesive 18 is suppressed.

Therefore, the emission of the stray light that has been incident on the adhesive 18 toward the image sensor 14 is suppressed, and emission of unnecessary light toward the image sensor 14 is prevented.

### [Application State of Adhesive]

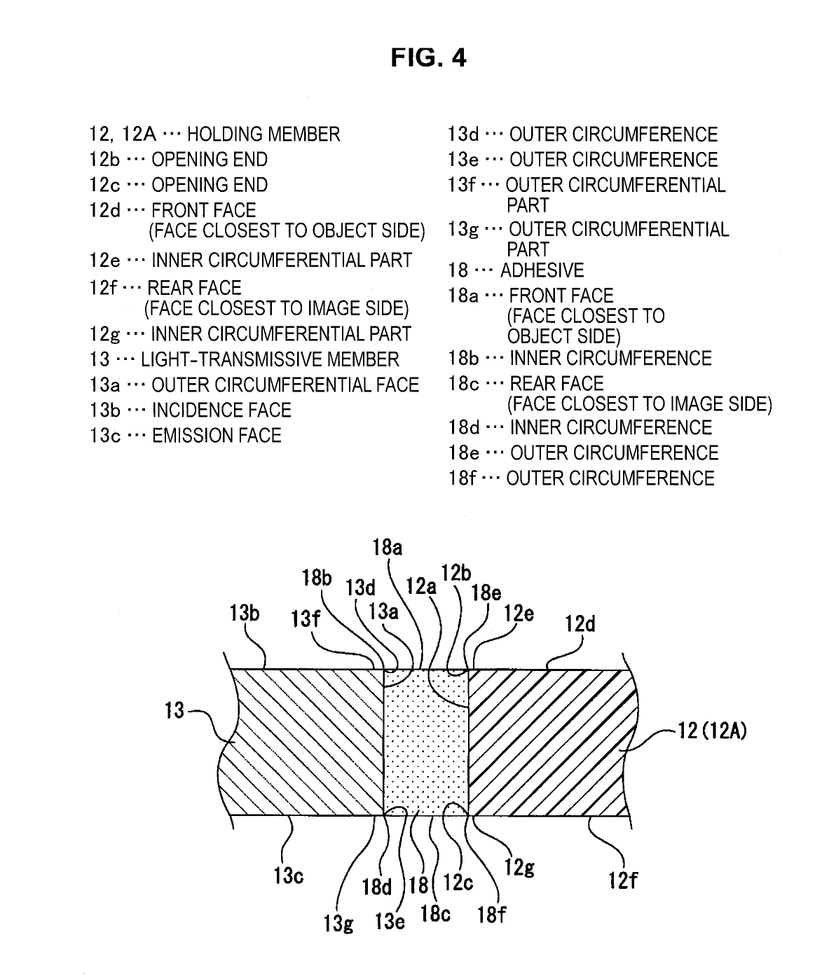

Hereinafter, an application state of the adhesive 18 in the imaging unit 10 will be described (refer to FIGS. 4 to 7).

In the imaging unit 10, it is desirable that at least one of an outer circumference 13d of the incidence face 13b and an outer circumference 13e of the emission face 13c of the light-transmissive member 13 coincide with at least one of an inner circumference 18b of a front face 18a and an inner circumference 18d of a rear face 18c of the adhesive 18 (refer to FIG. 4). Note that FIG. 4 shows an example in which the outer circumferences 13d and 13e of the light-transmissive member 13 respectively coincide with the inner circumferences 18b and 18d of the adhesive 18.

By causing at least one of the outer circumferences 13d and 13e of the light-transmissive member 13 to coincide with at least one of the inner circumferences 18b and 18d of the adhesive 18, the attachment area of the adhesive 18 to the outer circumferential face 13a of the light-transmissive member 13 is large, and accordingly, stray light approaching the image sensor 14 can be reduced.

In addition, by causing the outer circumferences 13d and 13e of the light-transmissive member 13 to respectively coincide with the inner circumferences 18b and 18d of the adhesive 18, the adhesive 18 is attached over the entire outer circumferential face 13a of the light-transmissive member 13, and accordingly, stray light approaching the image sensor 14 can be further reduced.

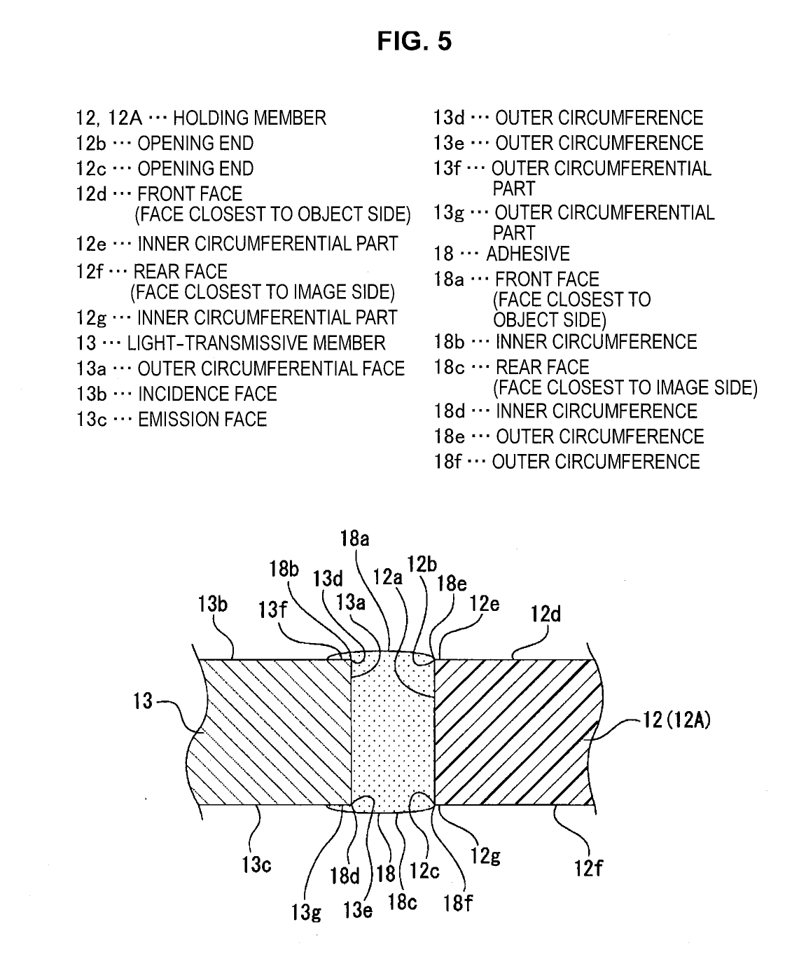

In the imaging unit 10, it is desirable that the adhesive 18 be applied to at least one of an outer circumferential part 13f of the incidence face 13b and an outer circumferential part 13g of the emission face 13c of the light-transmissive member 13 (refer to FIG. 5). Note that FIG. 5 shows an example in which the adhesive 18 is applied to both of the outer circumferential parts 13f and 13g of the light-transmissive member 13.

By applying the adhesive 18 to at least one of the outer circumferential parts 13f and 13g of the light-transmissive member 13 as described above, the attachment area of the adhesive 18 to the outer circumferential face 13a of the light-transmissive member 13 is large even when the adhesion position of the adhesive 18 to the light-transmissive member 13 is deviated, and accordingly, stray light approaching the image sensor 14 can be further reduced.

In addition, by applying the adhesive 18 to both of the outer circumferential parts 13f and 13g of the light-transmissive member 13, the adhesive 18 adheres to the entire outer circumferential face 13a of the light-transmissive member 13 even when the adhesion position of the adhesive 18 to the light-transmissive member 13 is deviated, and stray light approaching the image sensor 14 can be further reliably reduced.

Further, in the imaging unit 10, it is desirable that at least one of an opening end 12b on the front side and an opening end 12c on the rear side on the inner circumferential face 12a of the holding member 12 coincide with at least one of an outer circumference 18e of the front face 18a and an outer circumference 18f of the rear face 18c of the adhesive 18 (refer to FIG. 4). Note that FIG. 4 shows an example in which the opening ends 12b and 12c of the holding member 12 respectively coincide with the outer circumferences 18e and 18f of the adhesive 18.

By causing at least one of the opening ends 12b and 12c of the holding member 12 to coincide with at least one of the outer circumferences 18e and 18f as described above, the attachment area of the adhesive 18 to the inner circumferential face 12a of the holding member 12 is large, and accordingly, stray light approaching the image sensor 14 can be reduced.

In addition, by causing the opening ends 12b and 12c of the holding member 12 to respectively coincide with the outer circumferences 18e and 18f, the adhesive 18 is attached to the entire inner circumferential face 12a of the holding member 12, and accordingly, stray light approaching the image sensor 14 can be further reduced.

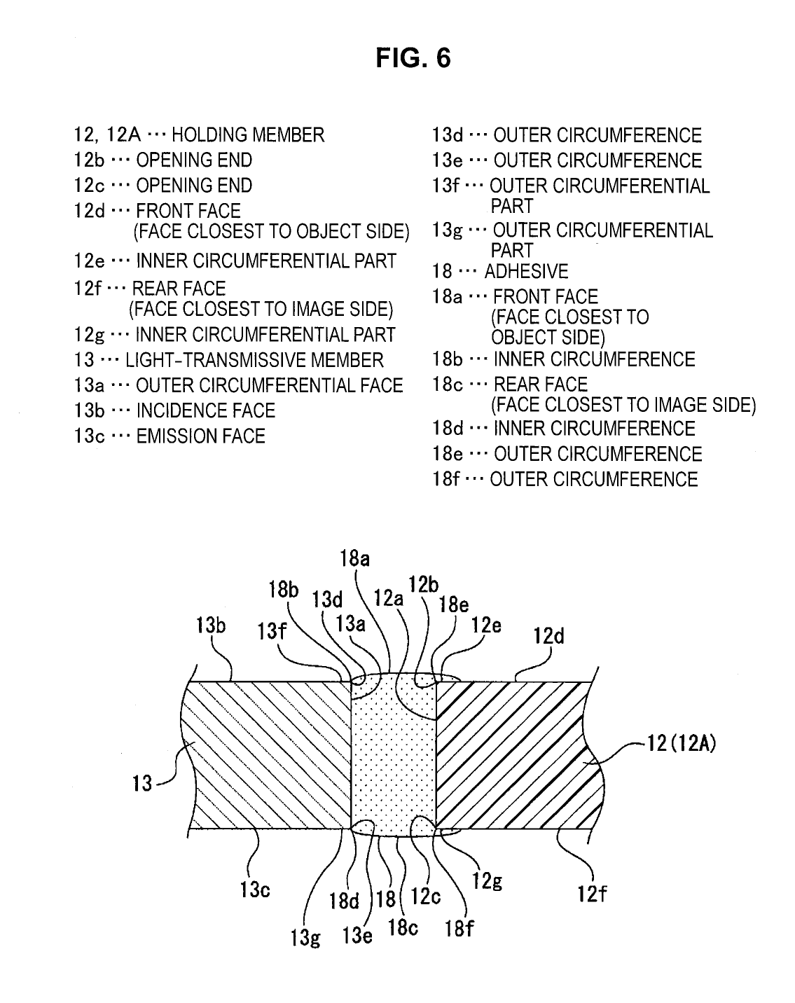

In the imaging unit 10, it is desirable that the adhesive 18 be applied to at least one of an inner circumferential part 12e of the front face 12d and an inner circumferential part 12g of the rear face 12f of the holding member 12 (refer to FIG. 6). Note that FIG. 6 shows an example in which the adhesive 18 is applied respectively to the inner circumferential parts 12e and 12g of the holding member 12.

By applying the adhesive 18 to at least one of the inner circumferential parts 12e and 12g of the holding member 12 as described above, the attachment area of the adhesive 18 to the inner circumferential face 12a of the holding member 12 is large even when the adhesion position of the adhesive 18 to the holding member 12 is deviated, and accordingly, stray light approaching the image sensor 14 can be even further reduced.

In addition, by applying the adhesive 18 to both of the inner circumferential parts 12e and 12f of the holding member 12, the adhesive 18 is attached to the entire inner circumferential face 12a of the holding member 12 even when the adhesion position of the adhesive 18 to the holding member 12 is deviated, and accordingly, stray light approaching the image sensor 14 can be further reliably reduced.

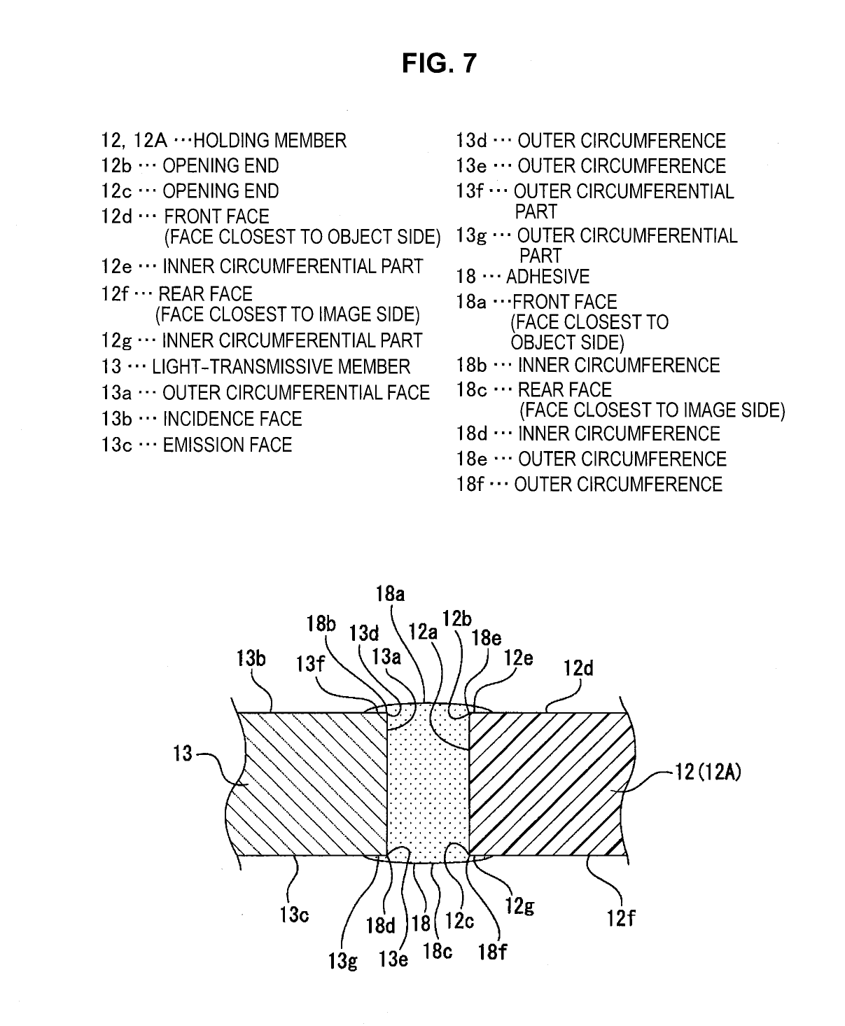

Note that, for the imaging unit 10, applying the adhesive 18 to the outer circumferential part 13f of the incidence face 13b and the outer circumferential part 13g of the emission face 13c of the light-transmissive member 13 and applying the adhesive 18 to the inner circumferential part 12e of the front face 12d and the inner circumferential part 12g of the rear face 12f of the holding member 12 are most desirable (refer to FIG. 7).

By applying the adhesive 18 to the outer circumferential parts 13f and 13g of the light-transmissive member 13 and the inner circumferential parts 12e and 12g of the holding member 12 as described above, the adhesive 18 is attached to the entire outer circumferential face 13a of the light-transmissive member 13 and the entire inner circumferential face 12a of the holding member 12 even when the adhesion position of the adhesive 18 to the light-transmissive member 13 or the holding member 12 is deviated, and accordingly, stray light approaching the image sensor 14 can be further reliably reduced.

### [Configuration of Imaging Unit According to Second Embodiment]

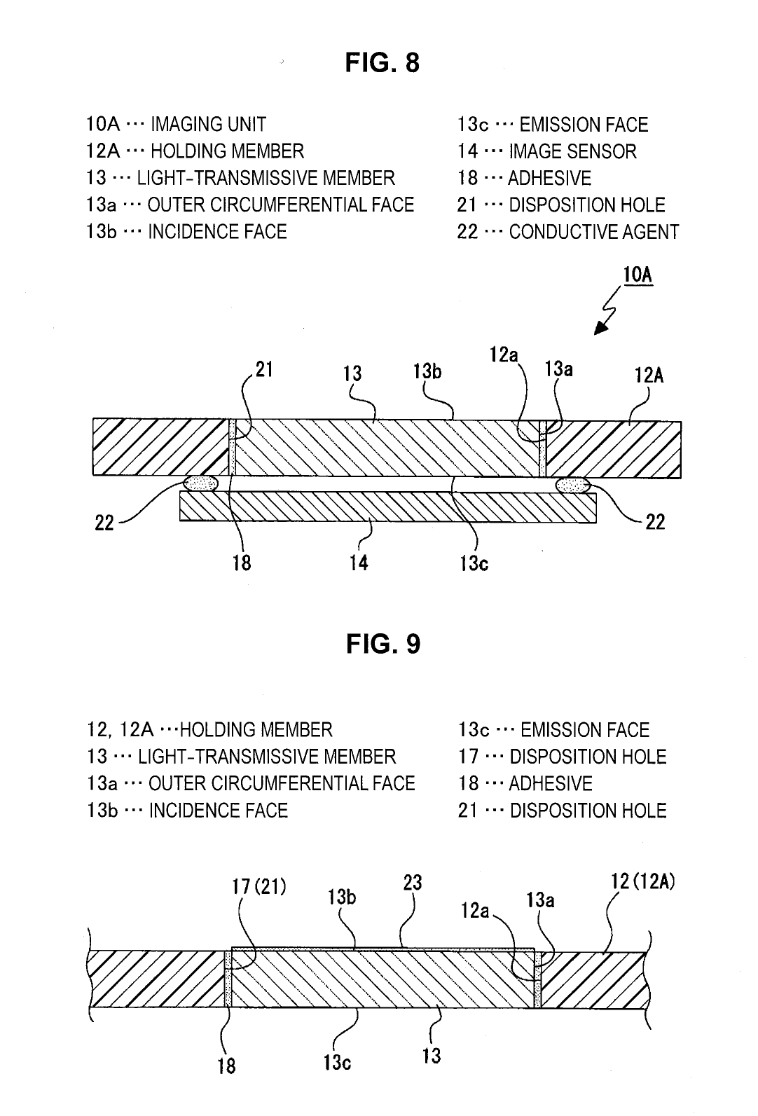

Next, an imaging unit 10A according to a second embodiment will be described (refer to FIG. 8).

Note that, in the imaging unit 10A according to the second embodiment to be shown below, the same light-transmissive member, image sensor, and adhesive are used when it is compared to the imaging unit 10 described above. Thus, in description with regard to the imaging unit 10A below, the same reference numerals will be given to the light-transmissive member, image sensor, and adhesive which are the same as those in the imaging unit 10, and detailed description thereof will be omitted.

The imaging unit 10A according to the second embodiment is disposed on the rear side of the lens unit 6. The imaging unit 10A has a holding member 12A, the light-transmissive member 13, and the image sensor 14.

The holding member 12A is a circuit board, and a circuit pattern that is not shown in the drawing is formed on the rear face of the holding member 12A. A rectangular disposition hole 21 penetrating in the front-rear direction is formed in the holding member 12A. The inner circumferential face 12a that extends in the circumferential direction in the disposition hole 21 is formed in the holding member 12A.

Using the adhesive 18, the light-transmissive member 13 adheres to and is held by the holding member 12A while being inserted in the disposition hole 21. Thus, the adhesive 18 is applied to the outer circumferential face 13a of the light-transmissive member 13 and the inner circumferential face 12a of the holding member 12A.

The image sensor 14 is formed in a rectangular shape slightly smaller than that of the light-transmissive member 13, bonded to the holding member 12A by means of flip-chip bonding using conductive agents 22, 22, . . . , and is disposed facing the light-transmissive member 13.

### [Incidence of Light on Imaging Unit According to Second Embodiment]

During imaging in the imaging device 1 having the imaging unit 10A, photographing light that is brought in via the optical system 9 is transmitted through the light-transmissive member 13 and then is incident on the image sensor 14, the incident photographing light is converted into electrical signals by the image sensor 14, and an image is thereby generated.

At this moment, part of light penetrating the lens unit 6 is incident from the incidence face 13b of the light-transmissive member 13 and then advances toward the outer circumferential face 13a as stray light (refer to the light A shown in FIG. 3). Since the refractive index of the adhesive 18 is set to be the same as that of the light-transmissive member 13, the stray light incident from the incidence face 13b is incident on the adhesive 18 from the outer circumferential face 13a without being reflected on the outer circumferential face 13a. The stray light incident on the adhesive 18 is absorbed by the adhesive 18 having light absorptivity, and stray light is not emitted from the adhesive 18 or emission from the adhesive 18 is suppressed.

Thus, the emission of the stray light that has been incident on the adhesive 18 toward the image sensor 14 is suppressed, and emission of unnecessary light toward the image sensor 14 is prevented.

### [Application State of Adhesive in Imaging Unit According to Second Embodiment]

Since the application state of the adhesive 18 in the imaging unit 10A is the same as that of the adhesive 18 in the imaging unit 10 (refer to FIGS. 4 to 7), description thereof will be omitted and only the reference numerals will be given for FIGS. 4 to 7.

### [Others]

In the description above, the example in which the light-transmissive member 13 is formed of parallel plate glass, a resin film, or the like in the imaging units 10 and 10A has been shown, but for example, a filter film 23 such as an infrared absorbing film, or the like may be formed on the front or rear face of the light-transmissive member 13 (refer to FIG. 9).

By forming the filter film 23 on the front or rear face of the light-transmissive member 13 in this manner, it is not necessary to separately dispose a dedicated filter on the optical path between the optical system 9 and the imaging units 10 or 10A, and thereby miniaturization of the imaging device 1 resulting from shortening of the length of the optical path can be attained.

### [Embodiment of Imaging Device]

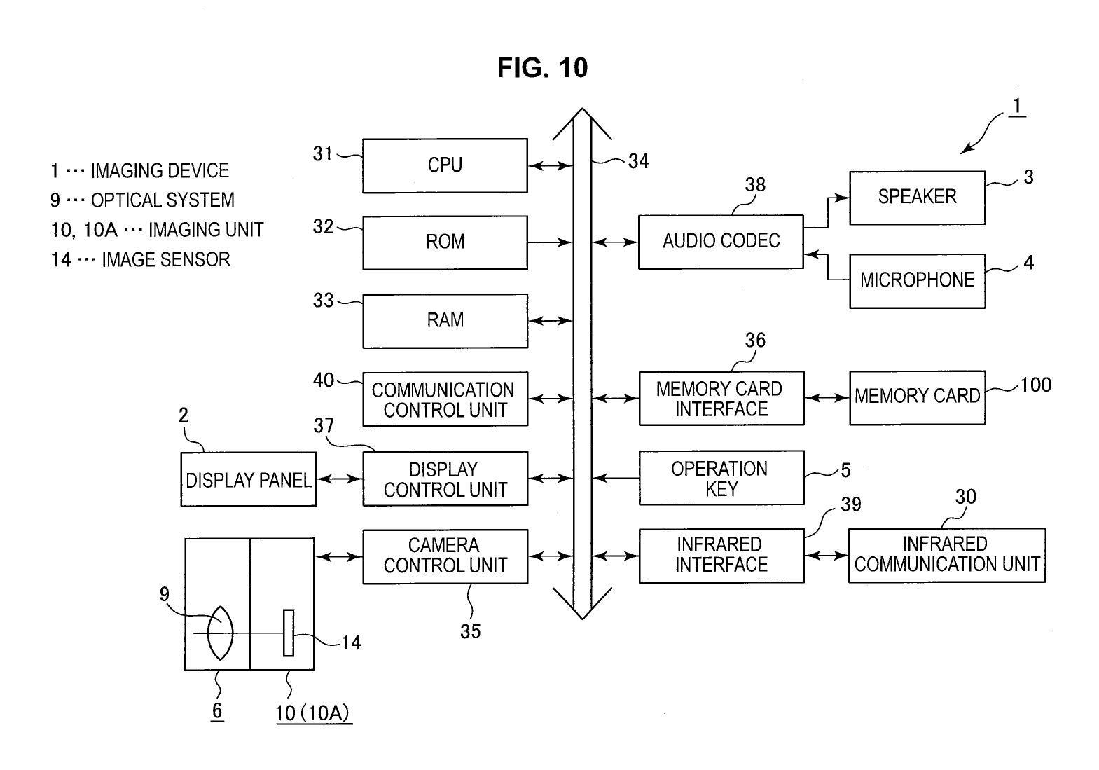

Next, an embodiment in which the imaging device according to the present disclosure is applied to a mobile telephone will be described (refer to FIG. 10).

A memory card 100 is inserted into or taken out from the imaging device (mobile telephone) 1.

In the imaging device 1, an infrared communication unit 30 for performing communication using infrared rays is provided.

The imaging device 1 includes a CPU (Central Processing Unit) 31, and the overall operation of the imaging device 1 is controlled by the CPU 31. The CPU 31 loads, for example, a control program stored in a ROM (Read Only Memory) 32 in a RAM (Random Access Memory) 33 to control the operation of the imaging device 1 via a bus 34.

A camera control unit 35 has a function of photographing still images and moving images by controlling the imaging unit 10 or 10A, performs compression processing for image information obtained from photographing in the form of a JPEG (Joint Photographic Experts Group), an MPEG (Moving Picture Expert Group), or the like, and then transfers the compressed data to the bus 34.

The image information transferred to the bus 34 is temporarily stored in the RAM 33, output to a memory card interface 36 if necessary, and then stored in the memory card 100 by the memory card interface 36, or displayed on a display panel 2 via a display control unit 37.

During imaging, audio information recorded through the microphone 4 at the same time is also temporarily stored in the RAM 33 via an audio codec 38, or stored in the memory card 100, and then output from the speaker 3 via the audio codec 38 at the same time as the image display on the display panel 2.

The image information and audio information are output to an infrared interface 39, output to outside via the infrared communication unit 30 by the infrared interface 39, and transmitted to other devices having the infrared communication unit, for example, mobile telephones, personal computers, PDA (Personal Digital Assistance), and the like. Note that, when a moving image or a still image is displayed on the display panel 2 based on the image information stored in the RAM 33 or the memory card 100, image data obtained by decoding or decompressing files stored in the RAM 33 or the memory card 100 in the camera control unit 35 is transferred to the display control unit 37 via the bus 34.

A communication control unit 40 performs transmission and reception of radio waves between base stations via an antenna not shown in the drawing. The communication control unit 40 processes received audio information in a voice calling mode, outputs the data to the speaker 3 via the audio codec 38, or receives sound collected using the microphone 4 via the audio codec 38, and performs a predetermined process on and then transmits the data.

### [Summary]

As described above, in the imaging units 10 and 10A, the light-transmissive member 13 adheres to and is held by the holding members 12 and 12A while the adhesive 18 is applied to the outer circumferential face 13a, and the adhesive 18 has light absorptivity and the same refractive index as the light-transmissive member 13.

Thus, since stray light approaching the outer circumferential face 13a of the light-transmissive member 13 is transmitted through the outer circumferential face 13a, is incident on the adhesive 18, and absorbed by the adhesive 18, incidence of unnecessary light on the image sensor 14 can be prevented.

In addition, even when the light-transmissive member 13 is disposed close to the image sensor 14, stray light approaching the outer circumferential face 13a of the light-transmissive member 13 is incident on and absorbed by the adhesive 18, and thus the incidence of unnecessary light on the image sensor 14 can be prevented while miniaturization of the imaging units 10 and 10A is secured.

Further, in the imaging unit 10 according to the first embodiment, a light shielding member is used as the holding member 12, the light shielding member is installed on the circuit board 11, and the disposition space 19 in which the image sensor 14 is disposed is formed.

Thus, by using the imaging unit 10 in the imaging device 1, the image sensor 14 is protected, adhesion of dust to the image sensor 14 is prevented, and further the incidence of unnecessary light on the image sensor 14 can be prevented.

On the other hand, in the imaging unit 10A according to the second embodiment, a circuit board is used as the holding member 12A, and the image sensor 14 is bonded to the holding member 12A using the conductive agents 22, 22, . . . .

Thus, by using the imaging unit 10A in the imaging device 1, thinness of the imaging unit 10A can be attained, and further the incidence of unnecessary light on the image sensor 14 can be prevented.

In addition, as described above, by setting the difference between refractive indexes of the light-transmissive member 13 and the adhesive 18 to be 0.3 or lower, the reflection of stray light toward the adhesive 18 from the light-transmissive member 13 on the surface of the adhesive 18 can be suppressed, and stray light approaching the image sensor 14 can be reduced.

Further, by setting the difference between refractive indexes of the light-transmissive member 13 and the adhesive 18 to be 0.2 or lower, the reflection of stray light toward the adhesive 18 from the light-transmissive member 13 on the surface of the adhesive 18 can be further suppressed, and stray light approaching the image sensor 14 can be further reduced.

Note that, as described above, by forming the adhesive 18 of a black material, or a material in which a black mixture is mixed, satisfactory light absorptivity of the adhesive 18 can be secured.

### [Present Technology]

Additionally, the present technology may also be configured as below.

(1) An imaging unit including:

a light-transmissive member through which photographing light brought in via an optical system is transmitted;

an image sensor that is disposed facing the light-transmissive member and on which photographing light that has been transmitted through the light-transmissive member is incident so as to convert the incident photographing light into electrical signals; and

a holding member that has a disposition hole and holds the light-transmissive member,

wherein the light-transmissive member has an outer circumferential face to which an adhesive is applied so as to be attached to and held by the holding member in a state of being disposed in the disposition hole, and

wherein the adhesive has light absorptivity and a refractive index that is substantially identical to a refractive index of the light-transmissive member.

(2) The imaging unit according to (1), further including:

a light shielding member serving as the holding member,

wherein the image sensor is mounted on a circuit board, and

wherein the holding member is installed on the circuit board and there is a disposition space in which the image sensor is disposed.

(3) The imaging unit according to (1), further including:

a circuit board serving as the holding member,

wherein the image sensor is bonded to the holding member by a conductive agent.

(4) The imaging unit according to any one of (1) to (3), wherein a difference between refractive indexes of the light-transmissive member and the adhesive is set to be 0.3 or lower.

(5) The imaging unit according to any one of (1) to (3), wherein a difference between refractive indexes of the light-transmissive member and the adhesive is set to be 0.2 or lower.

(6) The imaging unit according to any one of (1) to (5), wherein an outer circumference of at least one of an incidence face and an emission face of the photographing light of the light-transmissive member coincides with an inner circumference of at least one of a face of the adhesive closest to an object side and a face of the adhesive closest to an image side.

(7) The imaging unit according to (6), wherein the outer circumferences of the incidence face and the emission face of the light-transmissive member coincide with the inner circumferences of the face of the adhesive closest to the object side and the face of the adhesive closest to the image side, respectively.

(8) The imaging unit according to any one of (1) to (5), wherein the adhesive is applied to an outer circumferential part of at least one of an incidence face and an emission face of the photographing light of the light-transmissive member.

(9) The imaging unit according to (8), wherein the adhesive is applied to each of the outer circumferential parts of the incidence face and the emission face of the light-transmissive member.

(10) The imaging unit according to any one of (1) to (9), wherein at least one of an opening end of the disposition hole on an object side and an opening end of the disposition hole end on an image side in the holding member coincides with an outer circumference of at least one of a face of the adhesive closest to an object side and a face of the adhesive closest to an image side.

(11) The imaging unit according to (10), wherein the opening end on the object side and the opening end on the image side in the holding member coincide with the outer circumferences of the face of the adhesive closest to the object side and the face of the adhesive closest to the image side, respectively.

(12) The imaging unit according to any one of (1) to (9), wherein the adhesive is applied to at least one of an inner circumferential part of a face of the holding member closest to an object side and an inner circumferential part of a face of the holding member closest to an image side.

(13) The imaging unit according to (12), wherein the adhesive is applied to the inner circumferential part of the face of the holding member closest to the object side and the inner circumferential part of the face of the holding member closest to the image side.

(14) The imaging unit according to any one of (1) to (13), wherein the adhesive is formed of a black material or a material in which a black mixture is mixed.

(15) An imaging device including:

an optical system; and

an imaging unit that is disposed on an image side of the optical system,

wherein the imaging unit includes a light-transmissive member through which photographing light brought in via the optical system is transmitted, an image sensor that is disposed facing the light-transmissive member and on which photographing light that has been transmitted through the light-transmissive member is incident so as to convert the incident photographing light into electrical signals, and a holding member that has a disposition hole and holds the light-transmissive member,

wherein the light-transmissive member has an outer circumferential face to which an adhesive is applied so as to be attached to and held by the holding member in a state of being disposed in the disposition hole, and

wherein the adhesive has light absorptivity and a refractive index that is substantially identical to a refractive index of the light-transmissive member.

Specific shapes and configurations of each unit shown in the preferred embodiments described above are merely examples obtained by realizing the present disclosure, and the examples should not be used to restrictively interpret the scope of the present disclosure.

It should be understood by those skilled in the art that various modifications, combinations, sub-combinations and alterations may occur depending on design requirements and other factors insofar as they are within the scope of the appended claims or the equivalents thereof.

The present disclosure contains subject matter related to that disclosed in Japanese Priority Patent Application JP 2012-099121 filed in the Japan Patent Office on Apr. 24, 2012, the entire content of which is hereby incorporated by reference.

What is claimed is:

1. An imaging unit comprising:
a light-transmissive member through which photographing light brought in via an optical system is transmitted;
an image sensor that is disposed facing the light-transmissive member and on which photographing light that has been transmitted through the light-transmissive member is incident so as to convert the incident photographing light into electrical signals; and
a holding member that has a disposition hole and holds the light-transmissive member,
wherein the light-transmissive member has an outer circumferential face to which an adhesive is applied so as to be attached to and held by the holding member in a state of being disposed in the disposition hole, and
wherein the adhesive has light absorptivity and a refractive index that is substantially identical to a refractive index of the light-transmissive member.

2. The imaging unit according to claim 1, further comprising:
a light shielding member serving as the holding member,
wherein the image sensor is mounted on a circuit board, and
wherein the holding member is installed on the circuit board and there is a disposition space in which the image sensor is disposed.

3. The imaging unit according to claim 1, further comprising:
a circuit board serving as the holding member,
wherein the image sensor is bonded to the holding member by a conductive agent.

4. The imaging unit according to claim 1, wherein a difference between refractive indexes of the light-transmissive member and the adhesive is set to be 0.3 or lower.

5. The imaging unit according to claim 1, wherein a difference between refractive indexes of the light-transmissive member and the adhesive is set to be 0.2 or lower.

6. The imaging unit according to claim 1, wherein an outer circumference of at least one of an incidence face and an emission face of the photographing light of the light-transmissive member coincides with an inner circumference of at least one of a face of the adhesive closest to an object side and a face of the adhesive closest to an image side.

7. The imaging unit according to claim 6, wherein the outer circumferences of the incidence face and the emission face of the light-transmissive member coincide with the inner circumferences of the face of the adhesive closest to the object side and the face of the adhesive closest to the image side, respectively.

8. The imaging unit according to claim 1, wherein the adhesive is applied to an outer circumferential part of at least one of an incidence face and an emission face of the photographing light of the light-transmissive member.

9. The imaging unit according to claim 8, wherein the adhesive is applied to each of the outer circumferential parts of the incidence face and the emission face of the light-transmissive member.

10. The imaging unit according to claim 1, wherein at least one of an opening end of the disposition hole on an object side and an opening end of the disposition hole end on an image side in the holding member coincides with an outer circumference of at least one of a face of the adhesive closest to an object side and a face of the adhesive closest to an image side.

11. The imaging unit according to claim 10, wherein the opening end on the object side and the opening end on the image side in the holding member coincide with the outer circumferences of the face of the adhesive closest to the object side and the face of the adhesive closest to the image side, respectively.

12. The imaging unit according to claim 1, wherein the adhesive is applied to at least one of an inner circumferential part of a face of the holding member closest to an object side and an inner circumferential part of a face of the holding member closest to an image side.

13. The imaging unit according to claim 12, wherein the adhesive is applied to the inner circumferential part of the face of the holding member closest to the object side and the inner circumferential part of the face of the holding member closest to the image side.

14. The imaging unit according to claim 1, wherein the adhesive is formed of a black material or a material in which a black mixture is mixed.

15. An imaging device comprising:
an optical system; and
an imaging unit that is disposed on an image side of the optical system,
wherein the imaging unit includes a light-transmissive member through which photographing light brought in via the optical system is transmitted, an image sensor that is disposed facing the light-transmissive member and on which photographing light that has been transmitted through the light-transmissive member is incident so as to convert the incident photographing light into electrical signals, and a holding member that has a disposition hole and holds the light-transmissive member,
wherein the light-transmissive member has an outer circumferential face to which an adhesive is applied so as to be attached to and held by the holding member in a state of being disposed in the disposition hole, and
wherein the adhesive has light absorptivity and a refractive index that is substantially identical to a refractive index of the light-transmissive member.
